(19) United States
(12) Patent Application Publication
(10) Pub. No.: US 2018/0018743 A1
(43) Pub. Date: Jan. 18, 2018

(54) METHOD FOR CONSTRUCTING A PREDICTIVE MODEL

(71) Applicant: Schneider Electric Industries SAS, Rueil Malmaison (FR)

(72) Inventors: Michel CLEMENCE, Chambery (FR); Philippe DESCHAMPS, Le Pont de Claix (FR); Yves CHOLLOT, Meylan (FR); Clementine BENOIT, Grenoble (FR)

(73) Assignee: Schneider Electric Industries SAS, Rueil Malmaison (FR)

(21) Appl. No.: 15/647,299

(22) Filed: Jul. 12, 2017

(30) Foreign Application Priority Data
Jul. 18, 2016 (FR) 16 56826

(51) Int. Cl. G06Q 50/06; G06Q 10/06; H03J 3/14

(52) U.S. Cl. CPC G06Q 50/06; G06Q 10/06375; H03J 3/14

(57) ABSTRACT

A method for constructing a predictive model of a change of state of an electrical distribution network, the electrical distribution network including a node supplying power to loads connected by way of a distribution line, the method including: a. a step of measuring the variation, during a first time period, of a physical quantity A at the main node, and of a physical quantity B at measuring points of the network; and b. a step of correlating the quantity A and the quantity B measured in step a., so that knowledge of the physical quantity A at the main node allows the value of the physical quantity B at the plurality of measuring points of the network to be predicted.

### TECHNICAL FIELD

The present invention relates to a method for producing a model predictive of a characteristic quantity of an electrical distribution network. The invention also relates to the implementation of the model predictive of the characteristic quantity in order to ensure the stability of the electricity distribution network and, more particularly, of a low-voltage network.

### PRIOR ART

A low-voltage (LV) electricity distribution network (low-voltage meaning a power voltage lower than 1000 Volts) is generally supplied with current at a main node through which it is interfaced with a medium-voltage (MV) network (medium-voltage meaning a power voltage higher or equal to 1000 Volts) via a transformer station, referred to as an MV/LV station. An LV network also comprises a plurality of LV distribution lines which transport the current from the main node to users, for example domestic users, connected to said LV network.

This entire network is designed to guarantee consumers a predetermined voltage level. Fluctuations in LV distribution line voltage may nevertheless be observed when the consumption and/or the production of current by users varies. Therefore, in order to minimize voltage fluctuations, the MV/LV station may be servo-controlled by a regulation module intended to compensate for voltage fluctuations and thus keep the LV networks stable. Such a mode of servo-control is for example described in document FR 2 787 248.

However, these past few years have seen the emergence of decentralized electrical energy production sources, such as renewable energy sources, which also supply current to LV distribution lines. Certain users may be in possession of decentralized production sources that may produce electricity intermittently or in an uncontrolled fashion, in particular in the case of renewable energy sources, and as such lead to voltage imbalances between the various LV distribution lines that are connected to the main node. For example, the voltage of an LV distribution line may increase when it is supplied with current by a decentralized production source while the voltage of other LV distribution lines decreases due to an increase in user consumption.

Thus, the presence of decentralized production sources leads to disparities in the voltage level which make the aforementioned modes of regulation ineffective.

Furthermore, the regulation of the LV network using a transformer station requires knowledge of the behaviour of said line when encountering variations in voltage. However, lack of knowledge of the precise structure of the LV networks, hence of the various LV distribution lines of which it consists, prevents any modelling or construction of charts characterizing said LV distribution lines.

One aim of the present invention is to propose a method for determining a model predictive of a change of state of an electrical distribution network.

Another aim of the present invention is then to propose a method allowing the voltage of an electrical distribution network, for example an LV network, to be regulated.

### SUMMARY OF THE INVENTION

The aims of the invention are, at least in part, achieved by a method for constructing a model predictive of a change of state of an electrical distribution network, the predictive model being designed to implement a dynamic regulation of said electrical distribution network, the electrical distribution network comprising a main node supplying current to a plurality of loads that are connected to said main node via at least one distribution line, the method comprising:

a. a step of measuring, over a first time period, at least one physical quantity A at the main node, and at least one physical quantity B at a plurality of measuring points of the network;

b. a step, executed by a computer, of correlating the at least one quantity A and the at least one quantity B that were measured in step a., so that knowledge of the at least one physical quantity A at the main node allows the value of the at least one physical quantity B at the plurality of measuring points of the network to be predicted.

According to one mode of implementation, the correlation step b. comprises a machine learning algorithm, advantageously according to a support vector machine method.

According to one mode of implementation, the physical quantity A comprises at least one of the physical quantities chosen from among: voltage, current intensity, active power, reactive power.

According to one mode of implementation, the physical quantity B is a voltage.

According to one mode of implementation, the measurement step a. is carried out by a plurality of sensors located at the main node and at the plurality of measuring points.

According to one mode of implementation, the electrical distribution network comprises decentralized electrical energy production sources, advantageously the decentralized production sources comprise renewable energy sources.

According to one mode of implementation, the duration of the first time period is shorter than a month, advantageously shorter than a week.

According to one mode of implementation, the at least one distribution line is branched and comprises a plurality of terminals constituting points for measuring the physical quantity B.

According to one mode of implementation, the electrical distribution network comprises three phases and a neutral, the steps a. and b. being executed on the three phases and the neutral.

The invention also relates to a method for dynamically regulating an electrical distribution network comprising a main node supplying current to a plurality of loads that are connected to said main node via at least one distribution line, the value of at least one physical quantity B at a plurality of points of the electrical distribution network being correlated with the value of a physical quantity A at the main node according to the constructed predictive model.

The method comprises the prediction of the value of the at least one physical quantity B on the basis of the measurement of the value of the at least one physical quantity A, the method additionally comprises an adjustment of the value of the physical quantity A, through application of the predictive model, that is intended to keep the value of the at least one physical quantity B within a range of predetermined values.

According to one mode of implementation, the electrical distribution network is interfaced with a power supply network at the main node via a transformer station.

According to one mode of implementation, the adjustment of the physical quantity A is carried out by the transformer station.

According to one mode of implementation, the transformer station comprises a regulator that is intended to measure the value of the at least one physical quantity A and to predict the value of the at least one physical quantity B, said regulator also being suitable for controlling, at the transformer station, the adjustment of the value of the at least one physical quantity A.

According to one mode of implementation, the electrical distribution network is an LV network.

According to one mode of implementation, the electrical distribution network comprises decentralized electrical energy production sources, advantageously the decentralized production sources comprise renewable energy sources.

### BRIEF DESCRIPTION OF THE DRAWINGS

Other features and advantages will become apparent in the following description of modes of implementation of the method for constructing a model predictive of a change of state of an electrical distribution network according to the invention, given by way of non-limiting examples and with reference to the appended drawings in which:

FIG. 1 is a schematic representation of a distribution network intended to be regulated according to the invention;

FIG. 2 is a schematic diagram of the implementation of the construction of the predictive model according to the invention;

FIGS. 3a, 3b and 3c represent, for each of the phases a, b, and c of a three-phase low-voltage network, the variation in the voltages Vₐ, V_{b}, and V_{c} (on the vertical axis) with time (on the horizontal axis) of the voltage predicted by the predictive model according to the invention and the measured actual voltage.

### DETAILED DESCRIPTION OF PARTICULAR EMBODIMENTS

The invention described in detail below implements the construction of a model predictive of a change of state of an electrical distribution network that is intended to allow better regulation of the electricity distribution networks. More particularly, the method according to the invention implements a learning method intended to detect changes of state of the electricity distribution network, and thus allow the dynamic regulation thereof.

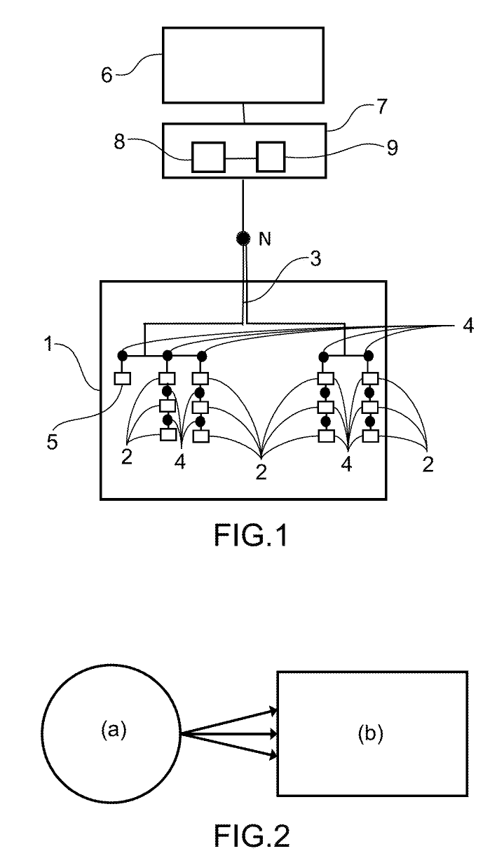

FIG. 1 represents an electrical distribution network 1. The electrical distribution network 1 is interfaced with a power supply network 6 from its main node N via a transformer station 7 comprising a transformer 8 (for example a MV/LV transformer).

At the node N (or at the transformer station 7), it is possible to count a plurality of distribution line 3 feeds supplying current to loads 2 (the term “loads” 2 is understood to mean members that consume electricity). For example, the electricity distribution network 1 may be an LV network connected to an MV network (the power supply network 6) via an MV/LV station from which it is possible to count between 1 and 20 distribution line 3 feeds.

The distribution lines 3 may be three-phase distribution lines (stated otherwise the distribution lines 3 comprise three phases and a neutral), and generally exhibit branching.

The electricity distribution network 1 may also comprise decentralized production sources 5. The term “decentralized production sources” 5 is understood to mean electricity production sources that are connected to said electricity distribution network 1 at the distribution lines 3, and at a distance from the main node 1.

The decentralized production sources are for example renewable energy production sources, more particularly photovoltaic energy sources or wind energy sources.

A first aspect of the invention, illustrated in FIG. 2, relates to setting up a model predictive of a change of state of the electrical distribution network 1. For example, the change of state of the electrical distribution network may correspond to a variation in the physical quantity B at at least one point of said network 1. More particularly, the physical quantity B may for example be a voltage. The change of state of the electrical distribution network may occur when the consumption of the loads 2 varies, or else when the decentralized production sources 5 inject current into the electrical distribution network 1.

The change of state of the electrical distribution network 1 is generally not uniform and thus leads to imbalances, of the voltage for example.

The method according to the invention therefore comprises a step a. of measuring at least one physical quantity A at the main node N. The term “measurement of at least one physical quantity A at the main node N” is understood to mean that the at least one physical quantity A is measured for each of the distribution line 3 feeds.

The measurement of the at least one physical quantity A may be taken by a plurality of sensors, referred to as “upstream sensors”, which are positioned at the main node N.

The at least one physical quantity A may comprise: voltage, current, active power P, reactive power Q.

Step a. also comprises the measurement of at least one physical quantity B at a plurality of measurement points 4 of the distribution network 1. The points 4 are learning points of the model that is the subject matter of the present invention. Therefore, throughout the description, reference will be made only to “points 4”, it being understood that “points 4” signifies learning points.

Advantageously, the measuring points 4 are positioned in proximity to the terminals of the distribution lines 3. The term “terminal of a distribution line 3” is understood to mean an end of said distribution line 3 other than its feed. The distribution lines 3 may be branched, it is then understood that they may comprise multiple terminals.

The measurement of the at least one physical quantity B may be taken by a plurality of sensors, referred to as “downstream sensors”, which are positioned at the measuring points 4.

Step a. is carried out in a first time period such that in said period the measurements of the at least one physical quantity A may be correlated with the measurements of the at least one physical quantity B.

The duration of the first time period may be shorter than a month, more particularly shorter than a week.

The measurement of the at least one physical quantity A and of the at least one physical quantity B may be taken continuously over the entire duration of the first time period.

The measurement of the at least one physical quantity A and of the at least one physical quantity B may be taken at regular intervals in time, for example every hour, over the first time period.

All of the measurements of physical quantities A and B constitute learning data.

The setup of the model predictive of a change of state of the electrical distribution network 1 also comprises a step b. allowing the at least one physical quantity A and the at least one physical quantity B to be correlated, for example by means of a machine learning method. Machine learning comprises the construction of a function f_{k,p} (the indices p and k relating to the phase and to the downstream sensor under consideration, respectively) on the basis of learning data, making it possible to predict the one or more values of the at least one physical quantity B at the points 4 on the basis of the measurement of the at least one physical quantity A.

The construction of the function f_{k,p} may comprise a step of minimizing the difference between the learning values of the physical quantity B (for example that measured by the downstream sensor k, V_{distant k,p}) and the prediction thereof by said function.

Machine learning may be implemented by means of a learning method referred to as support vector regression. The implementation of machine learning methods is known to those skilled in the art and, in this regard, a description of one of these methods will be found in the document [1] cited at the end of the description.

By way of example, the physical quantity B may be the voltage V_{distantk,p} at the points 4, and the at least one physical quantity A may comprise the voltage V_{N} and the current I_{N} at the main node N. The function f_{k,p} thus makes it possible to predict the voltage V_{distant k, p} at the points 4 of the electrical distribution network 1 on the basis of the measurement of the voltage V_{N} and the current I_{N} at the main point N (physical quantity A).

The predictive model according to the invention requires only the measurement of the at least one physical quantity A using just the upstream sensors positioned at the main node N. The downstream sensors positioned at the points 4 may be omitted.

The model according to the invention does not require a theoretical model of the behaviour of the electrical distribution network 1 to be set up.

Furthermore, the inventors have advantageously observed that simple knowledge of the voltage V_{N} and of the current I_{N} (V_{N} and I_{N} being the at least one quantity A) makes it possible to predict, with a sufficient degree of certainty, the voltage V_{distant} at the points 4 of the electrical distribution network 1.

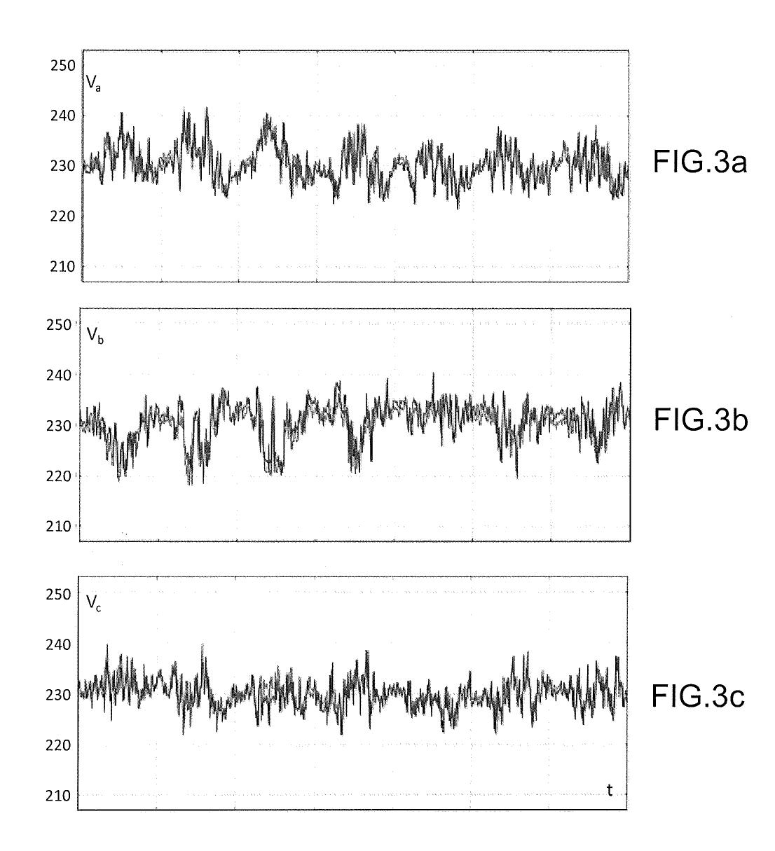

FIGS. 3a, b and c show the variation with time of the measured voltage and the voltage predicted using the predictive model at a point 4 for each of the phases a, b and c of a three-phase distribution network. The predictive model, in this example, links the voltage V_{N} and the current I_{N} at the main node N with the voltage V_{distant k, p} (physical quantity B) at the points 4.

The very small difference between the predicted voltage and the measured voltage validates the predictive model according to the invention which is distinguished as much by its simplicity of implementation as by its effectiveness with respect to models comprising modelling of the electrical distribution network.

Advantageously, the predictive model may be specific and distinguish, for example, the seasons, day from night, or else weekdays (from Monday to Friday) from weekend days (Saturday and Sunday). These distinctions make it possible to refine the predictive model and as such to endow it with greater accuracy.

The predictive model is advantageously implemented using a calculator, for example a computer. More specifically, the correlation step b) can be executed by the computer.

According to a second aspect, the invention also relates to a method for regulating the voltage of the electrical distribution network 1 implementing the predictive model described above.

The regulating method according to the invention aims to keep the at least one physical quantity B within a range of predetermined values at the points 4.

Furthermore, the regulating method according to the invention requires upstream sensors to be available only at the main node N of the electricity distribution network 1. Indeed, as soon as the predictive model is known, only the value of the physical quantity A is required to be able to predict the value of the physical quantity B at point 4.

More particularly, the predictive model may be used to regulate the value of the physical quantity B simply by adjusting the physical quantity A, for example in order to keep said physical quantity B within a range of predetermined values.

The physical quantity A may be adjusted by the transformer station 7.

More particularly, the transformer station may be provided with a regulator 9 that is intended to control the adjustment of the physical quantity A by the transformer 8.

Advantageously, the regulator 9 collects the measurement of the at least one physical quantity A from the upstream sensors that are positioned at the main node N, and predicts the value of the at least one physical quantity B at the points 4. As soon as a value of the at least one physical quantity B is outside the predetermined range of values, the regulator orders the transformer 8 to readjust the value of the at least one quantity A.

By way of example, the invention may be implemented in order to regulate an LV network that is interfaced, at its main node N, with an MV network via an MV/LV station. The MV/LV station allows the MV/LV network to be regulated. An MV/LV station of the “smart transformer” type described in patent application FR 3 004 284 allows the supply voltage of the LV network to be regulated dynamically.

### REFERENCES

[1] Alex J. Smola, Bernhard Schölkopf, “A tutorial on support vector regression”, Statistics and Computing, August 2004, Volume 14, Issue 3, pp. 199-222.

1. A method for constructing a model predictive of a change of state of an electrical distribution network, the predictive model being designed to implement a dynamic regulation of said network, the electrical distribution network comprising a main node supplying current to a plurality of loads that are connected to said main node via at least one distribution line, the method comprising:
a) a step of measuring the variation, over a first time period, of at least one physical quantity A at the main node, and of at least one physical quantity B at a plurality of measuring points of the network;
b) a step, executed by a computer, of correlating the at least one quantity A and the at least one quantity B that were measured in step a., so that knowledge of at least one physical quantity A at the main node allows the value of the at least one physical quantity B at the plurality of measuring points of the network to be predicted.

2. The method according to claim 1, wherein the correlation step b comprises a machine learning algorithm according to a support vector machine method.

3. The method according to claim 1, wherein the physical quantity A comprises at least one of the physical quantities chosen from the group consisting of voltage, current intensity, active power, and reactive power.

4. The method according to claim 1, wherein the physical quantity B is a voltage.

5. The method according to claim 1, wherein the measurement step a is carried out by a plurality of sensors located at the main node and at the plurality of measuring points.

6. The method according to claim 1, wherein the electrical distribution network comprises decentralized production sources, wherein the decentralized production sources comprise renewable energy sources.

7. The method according to claim 1, wherein the duration of the first time period is shorter than a month.

8. The method according to claim 1, wherein at least one distribution line is branched and comprises a plurality of terminals constituting points for measuring the physical quantity B.

9. The method according to claim 1, wherein the electrical distribution network comprises three phases and a neutral, the steps a and b being executed on the three phases and the neutral.

10. The method for dynamically regulating an electrical distribution network comprising a main node supplying current to a plurality of loads that are connected to said main node via at least one distribution line, the value of at least one physical quantity B at a plurality of points of the electrical distribution network being correlated with the value of a physical quantity A at the main node according to the predictive model constructed according to claim 1,
the method comprising the regulation of at least one physical quantity A so as to keep the value of the at least one physical quantity B within a range of predetermined values.

10. The method according to claim 10, wherein the electrical distribution network is interfaced with a power supply network at the main node via a transformer station.

11. The method according to claim 11, wherein the adjustment of the physical quantity A is carried out by the transformer station.

12. The method according to claim 11, wherein the adjustment of the physical quantity A is carried out by the transformer station.

13. The method according to claim 12, wherein the transformer station comprises a regulator that is intended to measure the value of at least one physical quantity A and to predict the value of at least one physical quantity B, said regulator also being suitable for controlling, at the transformer station, the adjustment of the value of the at least one physical quantity A.

14. The method according to claim 10, wherein the electrical distribution network is an LV network.

15. The method according to claim 10, wherein the electrical distribution network comprises decentralized production sources, wherein the decentralized production sources comprise renewable energy sources.
